(19) United States
(12) Patent Application Publication
(10) Pub. No.: US 2011/0198680 A1
(43) Pub. Date: Aug. 18, 2011

(54) Non-Volatile Memory Device Including Quantum Dots Embeded in Oxide Thin Film, and Fabrication Method of the Same

(75) Inventor: Eui-Tae Kim, Daejeon (KR)

(73) Assignee: The Industry & Academic Cooperation in Chungnam National Univesity (IAC), Daejon (KR)

(21) Appl. No.: 12/711,151

(22) Filed: Feb. 23, 2010

(30) Foreign Application Priority Data
Feb. 17, 2010 (KR) 10-2010-0014182

(51) Int. Cl. H01L 29/792; H01L 21/336

(52) U.S. Cl. 257/314; 438/763; 257/E29.309; 257/E21.423; 977/774

(57) ABSTRACT

A non-volatile memory device is provided in which quantum dots are embedded in an oxide thin film formed on a substrate. A conventional Si CMOS process can be used to manufacture the non-volatile memory device in a cost-effective way. Also, a photonic device and an electronic/photonic device, which can store a light signal or emit a stored signal as light, can be produced on a Si wafer in a cost-effective manner.

### CROSS-REFERENCE TO RELATED APPLICATIONS

This application claims the benefit of Korean Patent Application No. 2010-14182, filed on Feb. 17, 2010, which is incorporated herein by reference in its entirety.

### BACKGROUND

1. Technical Field

The present invention relates to a non-volatile memory device including quantum dots embedded in an oxide and a fabrication method thereof.

2. Background Art

Semiconductor memories are classified into two groups: a volatile random access memory (VRAM) and a non-volatile random access memory (NVRAM). Typical examples of the VRAM may include static RMA (SRAM) and dynamic RAM (DRAM). The SRAM has very high speed, but has a low level of integration, and thus is used mainly for a cache or high-speed memory. The DRAM has a simple structure, is advantageous for large-capacity systems, and thus a large market size. However, the DRAM consumes much power, because the information stored therein is volatile and the same information is stored again in a very short interval.

Accordingly, an NVRAM device, which is inexpensive and, at the same time, satisfies a high storage density comparable to that of the DRAM and a high speed comparable to that of the SRAM, has received attention as a next-generation memory. Accordingly, memory device technologies have advanced to improve the integration density, reliability and response speed of memory devices, and a memory device employing nanocrystalline quantum dots has been spotlighted as a next-generation memory technology.

Semiconductor quantum dots are nanocrystals having a size of several to several tens of nanometers and show unique electrical and optical properties which differ from those of quantum wells or quantum wires, particularly in that the energy-state density has the delta-function property. Particularly, thanks to their advantages such as excellent quantum properties and light-emitting properties, studies on the application of quantum dots to electronic and photoelectronic devices such as memory devices or light-emitting diode devices have recently been actively conducted (see D. Goldhaber-Gordon, M. S. Montemerlo, J. C. Love, G. J. Opiteck, and J. C. Ellenbogen, Overview of Nanoeletronic Devices, (The Proceedings of IEEE, 1997); E. T. Kim, Z. H. Chen, and A. Madhukar, Appl. Phys. Lett., 79, 3341 (2001); A. P. Alivisatos, Science, 271, 933 (1996); X. Peng, L. Manna, W. Yang, J. Wickham, E. Scher, A. Kadavanich, and A. P. Alivistos, Nature, 404, 59 (2000); C. B. Murray, D. J. Norris, and M. G. Bawendi, J. Am. Chem. Soc., 115, 8706 (1993); S. Coe, W. K. Woo, M. Bawendi, and V. Bulovic, Nature, 420, 800 (2002); M. P. Bruchez, M. Moronne, P. Gin, S. Weiss, and A. P. Alivisatos, Science, 281, 2013 (1998); W. C. W. Chan and S. Nie, Science, 281, 2016 (1998); B. Dubertret, P. Paris, D. J. Norris, V. Noireaux, A. H. Brivanlouand A. Libchaber, Science, 298, 1759 (2002); J. Lee, V. C. Sundar, J. R. Heine, M. G. Bawendi, and K. F. Jensen, Adv. Mater., 12, 1102 (2000); and W. Huynh, J. J. Dittmer, and A. P. Alivisatos, Science, 295, 2425 (2002))).

An NVRAM device employing semiconductor utilizing semiconductor quantum dots is generally a nano-floating gate memory (NFGM) in which the floating gate is replaced with an array of quantum dots. Methods for fabricating quantum dots include a method comprising inserting an ion or electron in a desired location using a focused ion beam (FIB) or electron beam. According to this method, the size and the location of formation of a quantum dot are controlled in a favorable way, but the commercial use of the method is limited because of low productivity. Another method for fabricating quantum dots is a method of forming crystal nuclei. Such a method comprises forming an amorphous thin film, and then thermally treating the thin film to form a single crystal as a quantum dot. This method is favorable in view of productivity, but has difficulty in controlling the size and the distribution of the quantum dots.

In addition, a method of fabricating quantum dots by a colloidal process has recently received a great deal of attention. According to this method, quantum dots made of various materials can be selectively fabricated in various sizes by selecting a suitable precursor and controlling the kind, concentration and growth temperature of ligand which is used in a reaction (see A. P. Alivisatos, Science, 271, 933 (1996); X. Peng, L. Manna, W. Yang, J. Wickham, E. Scher, A. Kadavanich, and A. P. Alivistos, Nature, 404, 59 (2000); C. B. Murray, D. J. Norris, and M. G. Bawendi, J. Am. Chem. Soc., 115, 8706 (1993)). However, the semiconductor quantum dots fabricated by the colloidal process have limited use, because they mostly used in a solution state or a form coupled to a polymer material which can be dissolved or dispersed in a solution (see S. Coe, W. K. Woo, M. Bawendi, and V. Bulovic, Nature, 420, 800 (2002); J. Lee, V. C. Sundar, J. R. Heine, M. G. Bawendi, and K. F. Jensen, Adv. Mater., 12, 1102 (2000); W. Huynh, J. J. Dittmer, and A. P. Alivisatos, Science, 295, 2425 (2002); and Korean Patent Application Publication No. 10-2006-73077).

There is still need for a new non-volatile memory device, a method for preparing the same, and electronic/photonic devices resulting therefrom.

The above information disclosed in this Background section is only for enhancement of understanding of the background of the invention and therefore it may contain information that does not form the prior art that is already known in this country to a person of ordinary skill in the art.

### SUMMARY OF THE INVENTION

Accordingly, the present invention has been made to solve the above-mentioned problems occurring in the prior art, and it is an object of the present invention to provide a non-volatile memory device having a structure in which semiconductor quantum dots are embedded in an oxide.

Another object of the present invention is to provide a method for fabricating a non-volatile memory device having such a structure.

(1) To achieve the above objects, in one aspect, the preset invention provides a non-volatile memory device comprising an oxide thin film formed on a substrate, wherein the oxide thin film has quantum dots embedded therein.

Preferably the substrate may be a p-type or n-type and is made of Si or GaAs semiconductor.

The oxide may be one or two or more selected from the group consisting of TiO₂, SiO₂, Hf₂O₃, Y₂O₃, ZrO₂, Al₂O₃, Cu₂O, BN, MnO and V₂O₃.

In one embodiment of the present invention, the quantum dots may be made of one or a mixture of two or more selected from the group consisting of CdS, CdSe, CdSe/ZnS, PbS, CdTe, ZnS, ZnSe, ZnTe, GaN, GaP, GaAs, GaSb, AlN, Alp, AlAs, AlSb, InP, InAs, InSb and SiC. However, the quantum dots may also be made of one or a mixture of two or more selected from materials having properties similar to those of the above quantum dot materials, which are known in the art or will be developed in the future.

Meanwhile, a ligand remaining after it has been used in a process of embedding quantum dots into an oxide thin film during the fabrication of a device can significantly deteriorate the properties of the device by forming a binding energy level at the interface between the oxide thin film and the quantum dot. For this reason, the quantum dot in the present invention is preferably in the state in which a ligand bound to the surface of the quantum dot has been removed.

As can be seen in Examples below, the device according to the present invention shows capacitance-voltage (C-V) characteristics suitable for non-volatile memory devices. In other words, at a negative voltage, holes are trapped by the quantum dots to show a memory effect, and at a positive voltage, electrons are trapped by the quantum dots to show a memory effect. For example, in the device of the present invention comprising a p-type substrate, when a positive voltage is applied, electrons are trapped by the quantum dots so that an electronic signal is stored, and when a negative voltage is applied, the memory is erased.

(2) Also, in another aspect, the present invention provides a method for fabricating a non-volatile memory device comprising an oxide thin film formed on a substrate, the method comprising the steps of: (A) coating a substrate with quantum dots; and (B) depositing an oxide thin film on the substrate having the quantum dots coated thereon, whereby the oxide thin film is formed on the non-volatile memory device.

After step (B), a suitable lithographic process and etching process may be performed according to conventional methods.

In one embodiment of the present invention, a ligand on the surface of the quantum dots used in step (A) can be substituted with SHCH₂CH₂OOH (MPA).

The deposition in step (B) of the method of the present invention can be performed by plasma metal organic chemical vapor deposition at 100-200° C. If the deposition temperature is lower than 100° C., defects will occur on the oxide thin film to reduce the quality of the oxide thin film, and if the deposition temperature is higher than 200° C., the quantum dots will be thermally decomposed to significantly reduce the memory and photoluminescence efficiencies of the device.

Meanwhile, a ligand remaining after it has been used in the step of quantum dots into the oxide thin film during the fabrication of the device can form a binding energy level at the interface between the oxide thin film and the quantum to significantly deteriorate the properties of the device. For this reason, the method of the present invention preferably additionally comprises, between step (A) and step (B), a step of removing a ligand from the coated quantum dots. For this purpose, the surface coated with the quantum dots can be subjected to hydrogen plasma treatment at 50-150° C. If the treatment temperature is lower than 50° C., the ligand removal effect will be insufficient, and if the treatment temperature is higher than 150° C., the quantum dots will be thermally decomposed to significantly reduce the memory and photoluminescence efficiencies of the device.

The hydrogen plasma treatment is preferably carried out at an RF power of 40 W for more than 10 minutes. If the treatment time is less than 10 minutes, the ligand will not be completely removed. If the treatment time is more than 10 minutes, there is little or no change in the properties of the interface, and thus the upper limit of the treatment time is not necessarily established.

According to the present invention, a non-volatile memory device including various semiconductor quantum dots embedded in an oxide can be economically produced using a conventional Si CMOS process.

Also, according to the present invention, a photonic device and an electronic/photonic device, which can store a light signal or emit a stored signal as light, can be produced on a Si wafer in a cost-effective manner.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a graphic diagram showing the photoluminescence properties of CdSe/ZnS quantum dots, which result from surface modification in an embodiment of the present invention;

FIG. 2 is a graphic diagram showing the photoluminescence properties of CdSe/ZnS quantum dots, which result from hydrogen plasma treatment at various reaction temperatures in an embodiment of the present invention;

FIG. 3 illustrates a non-volatile memory MOS structure according to an embodiment of the present invention;

FIG. 4 is a graphic diagram showing the 1 MHz C-V characteristics of a TiO₂ thin film having no quantum dot embedded therein (a reference sample), a TiO₂ thin film device having embedded therein TOPO-quantum dots, and a TiO₂ thin film device having embedded therein MPA-quantum dots; and

FIG. 5 is a graphic diagram showing the change in the C-V characteristics of TOPO-quantum dots (a) and the change in the C-V characteristics of MPA-quantum dots (b) with the change in hydrogen plasma treatment time according to the present invention.

### DETAILED DESCRIPTION OF EMBODIMENTS

Hereinafter, the present invention will be described in further detail with reference to the accompanying drawings, preparatory experiments and examples. It is to be understood, however, that these drawings, preparatory experiments and examples are for illustrative purposes only and are not to be construed to limit the scope of the present invention. It will be obvious to a person skilled in the art that other various modifications and variations are possible within the scope of the present invention.

It should be noted that although a CdSe/ZnS quantum dot was used as a quantum dot, TOPO as a ligand, and MPA as a substituent in the following preparatory experiments and examples, it will be apparent to a person skilled in the art that the use of other materials as a quantum dot, a ligand and a substituent can show the identical or similar results to those obtained using the above-described materials.

Preparatory Experiment 1: Preparation of Cdse/Zns Quantum Dots, Surface Modification, and Analysis of Properties

1. Preparation of Cdse/Zns Quantum Dots

According to a pyrolysis process, CdSe/ZnS nanocrystalline quantum dots having a core-shell structure were prepared.

2.7 mg of CdO and 160 mg of lauric acid were added into a three-neck rounded-bottom flask in an Ar gas atmosphere and heated to 200° C. Then, triotylphospine oxide (TOPO) and hexadecylamine (HDA) were added thereto in amounts of 1.8 g and 2.5 g, respectively. The mixture was heated to 240° C., the synthesis temperature of desired CdSe quantum dots, and then an Se precursor solution obtained by dissolving 80 mg of Se in 2 ml of trioctylphospine (TOP) was added thereto rapidly within 1 second and allowed to react, thus synthesizing CdSe quantum dots.

Then, to form a ZnS shell structure, the internal temperature of the flask was lowered to 200° C.:, and a Zn—S precursor [prepared by mixing 1 ml of diethylzinc(ZnEt₂) with 250 μl of hexamethyldisilathiane ((TMS)₂S) and 2 ml of TOP] was added into the flask dropwise over 1 minute. After the Zn—S precursor has been added, the internal temperature of the flask was lowered to 180° C. and maintained at that temperature for 1 hour, thus forming a ZnS shell structure. After completion of the reaction, the flask was cooled to room temperature and washed 3-5 times with a mixed solution of chloroform and methanol, thus obtaining CdSe/ZnS quantum dots.

2. Surface Modification of Cdse/Zns Quantum Dots

The ligand TOPO used in the preparation of the CdSe/ZnS quantum dots has a non-polar long chain structure, and thus, if the ligand is bound to the surface of the quantum dots, it is disadvantageous in terms of the introduction of electrons and holes into the quantum dots. In comparison with this, MPA has a polar short chain structure, unlike TOPO, and has a boiling point of about 110° C. which is lower than the boiling point (about 200° C.) of TOPO. Thus, MPA is very easily removed before embedding the quantum dots into an oxide thin film. For these reasons, the TOPO ligand of the CdSe/ZnS quantum dots prepared as described above was substituted with MPA.

Meanwhile, in this Example, although the quantum dots prepared as described above were used, quantum dots prepared by other methods known in the art may also be used in the same manner as described in this Example.

The quantum dots are surface-modified in the following manner.

(a) 1 ml of MPA and 30 ml of methanol were added into a three-neck flask in an Ar gas atmosphere. (b) In a dark condition, 0.5 ml of a solution containing 1 wt % of the above-prepared quantum dots diluted therein was added into the flask and allowed to react with stirring at 75° C. for 6 hours. (c) Ethyl acetate and ether were added into the flask, and the flask was cooled to room temperature and washed several times with methanol. (d) The resulting solution was stored in a mixed solution of methanol and water.

3. Analysis of Optical Properties of Surface-Modified Cdse/Zns Quantum Dots

The optical properties of the surface-modified quantum dots were analyzed by photoluminescence (PL) using a 325-nm He—Cd laser.

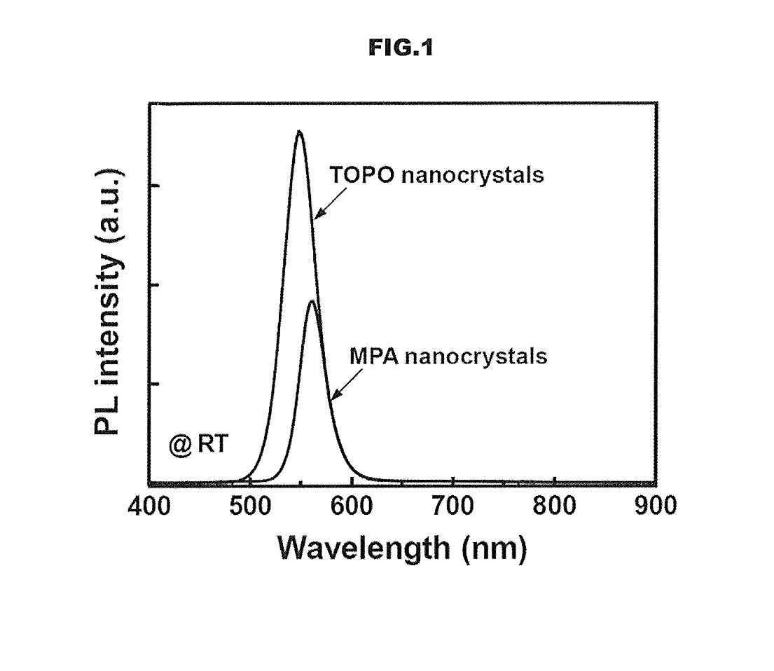

As shown in FIG. 1, the CdSe/ZnS quantum dots having the TOPO ligand (hereinafter referred to as “TOPO-quantum dots”) showed strong photoluminescence intensity at 550 nm. However, in the case of the CdSe/ZnS quantum dots surface-modified with MPA (hereinafter referred to as “MPA-quantum dots”), the PL intensity was decreased and the photoluminescence position was slightly shifted toward the long wavelength side (560 nm).

Without intending to limit the theory, the decrease in the photoluminescence intensity is believed to be because a binding energy level could occur on the surface of the quantum dots by a chemical influence during the surface modification process and/or because the surface of the quantum dots was not effectively surrounded by MPA, leading to a decrease in quantum efficiency.

Preparatory Experiment 2: Removal of Ligand from Cdse/Zns and Analysis of Properties

1. Removal of Ligand Using Hydrogen Plasma

The TOPO-quantum dots were spin-coated on a p-type Si substrate, and then placed into a PEMOCVD chamber. Then, a mixed gas of Ar and H₂ (10%) was introduced into the chamber at a flow rate of 200 SCCM, and RF plasma of 40 W was applied to the chamber at 1.2 Torr for 10 minutes, thus removing the ligand. The plasma treatment process was carried out at each of 100° C., 200° C. and 300° C.

2. Analysis of Optical Properties of Cdse/Zns Quantum Dots from which Ligand has been Removed

The optical properties of the surface-modified quantum dots were analyzed by photoluminescence using a 325-nm He—Cd laser.

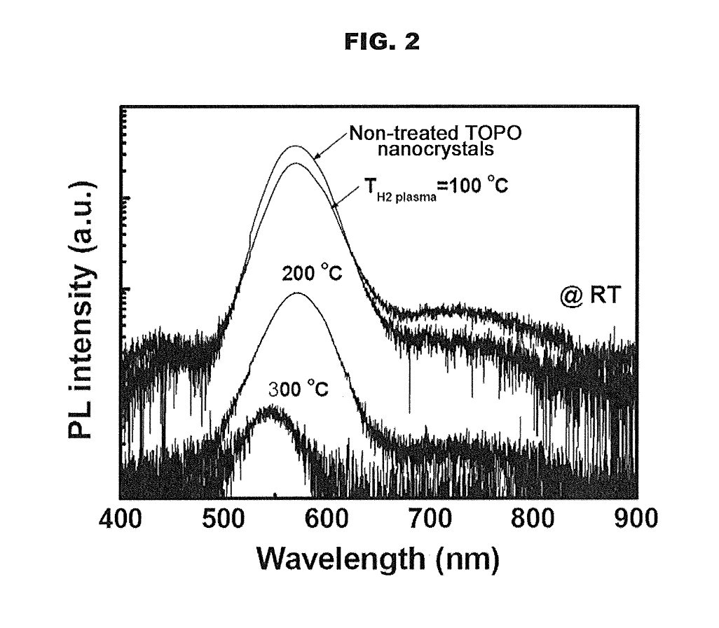

As can be seen in FIG. 2, the quantum dots treated with plasma at 100° C. did not show a great difference from non-treated quantum dots with respect to photoluminescence properties, but the quantum dots treated with plasma at a temperature higher than 200° C. showed a great decrease in photoluminescence efficiency. Among others, at 300° C., the photoluminescence efficiency of the quantum dots was greatly decreased and the photoluminescence position was shifted toward the short wavelength side.

Without intending to limit the theory, it is considered that, when the plasma treatment is carried out at 200° C., the quantum dots are thermally damaged and the surface thereof is damaged by plasma, leading to a great decrease in the photoluminescence efficiency, and when the plasma treatment is carried out at a temperature higher than 300° C., the quantum dots are decomposed such that the size thereof is decreased and the quantum dot properties are lost.

### Example: Fabrication of Non-Volatile Memory Device and Analysis of Device Properties

1. Fabrication of Non-Volatile Memory Device

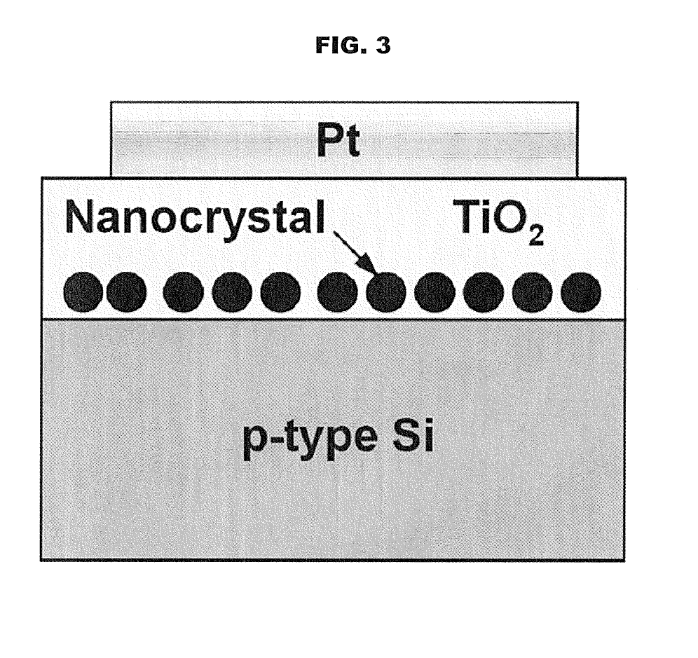

Using the TOPO-quantum dots or the MPA-quantum dots, a non-volatile memory MOS having a structure illustrated in FIG. 3 was fabricated.

(1) First, the quantum dots were uniformly dispersed on a p-type Si substrate by a spin-coating process, and then an organic solvent (e.g., chloroform, methanol, etc.) was removed from the substrate (by allowing the substrate to stand for 20-30 minutes such that the solvent is evaporated by natural vaporization).

(2) Then, if necessary, the ligand of the quantum dots was removed using hydrogen plasma at 100° C.

(3) Then, a TiO₂ thin film having a thickness of about 50 nm was deposited on the substrate. The deposition of the TiO₂ thin film was performed by a plasma-enhanced metal organic chemical vapor deposition (PEMOCVD) process which is suitable for Si processes and also allows deposition even at a relatively low temperature lower than 200° C. As a Ti organometallic precursor, titanium tetraisopropoxide (Ti(OiC₃H₇)₄) forming good-quality TiO₂ even at a temperature lower than 200° C. was used, and the precursor was bubbled with 50 SCCM of argon gas at 30° C. and introduced into the reaction chamber. The deposition was carried out in the following conditions: deposition temperature: 200° C.; RF plasma power: 50 W; deposition pressure: 1.2 Torr; oxygen gas flow rate: 50 SCCM; and total gas flow rate: 200 SCCM.

A study conducted by the present inventors showed that the deposition temperature at which thermal damage to the CdSe/ZnS quantum dots during TiO₂ deposition is minimized is about 200° C. Accordingly, the TiO₂ deposition process was carried out at about 200° C.

(4) After TiO₂ has been deposited, Pt was deposited on the substrate to a thickness of about 0.1 μm by a sputtering deposition process to form a gate electrode layer.

(5) Then, the substrate was subjected to a conventional lift-off process, thus fabricating a non-volatile memory device comprising a gate electrode having a diameter of 200 μm.

2. Analysis of Effect of Quantum Dot Ligand on C-V Characteristics of Memory Device

The capacitance-voltage (C-V) characteristics of the memory device fabricated in the above section 1 were analyzed.

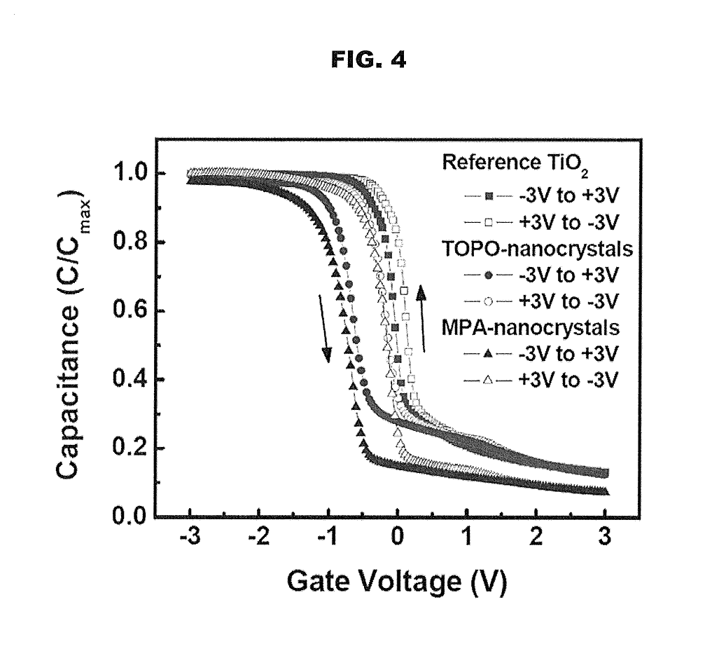

FIG. 4 shows the 1 MHz C-V characteristics of a TiO₂ thin film having no quantum dot embedded therein (a reference sample), a TiO₂ thin film MOS structure having embedded therein TOPO-quantum dots, and a TiO₂ thin film MOS structure having embedded therein MPA-quantum dots.

As can be seen in FIG. 4, the device including the TOPO-quantum dots and the device including the MPA-quantum dots showed hysteresis widths of 0.46 V and 0.61 V, respectively, which were larger than that of the reference sample. Such results suggest that the quantum dots contribute to the charge memory effect.

Also, the device including the MPA-quantum dots showed a hysteresis width larger than that of the device including the TOPO-quantum dots. This is, without intending to limit the theory, believed to be because MPA is advantageous for the introduction of electrons and holes into the quantum dots than TOPO.

Also, in the cases of the device including the TOPO-quantum dots and the device including the MPA-quantum dots, the flat band voltage in sweep up (+3V→−3V) was not greatly changed compared to the reference sample, but the flat band voltage in sweep down (−3V→+3V) was shifted in the negative direction. Without intending to limit the theory, it is believed that this occurs because quantum dots are mostly charged with holes rather than electrons.

3. Analysis of Effect of Removal of Ligand from Quantum Dots on C-V Characteristics of Memory Device

In order to improve the electron charging memory effects inhibited by the influence of the quantum dot ligand as described in the above section 2, devices including quantum dots with the ligand removed therefrom were fabricated.

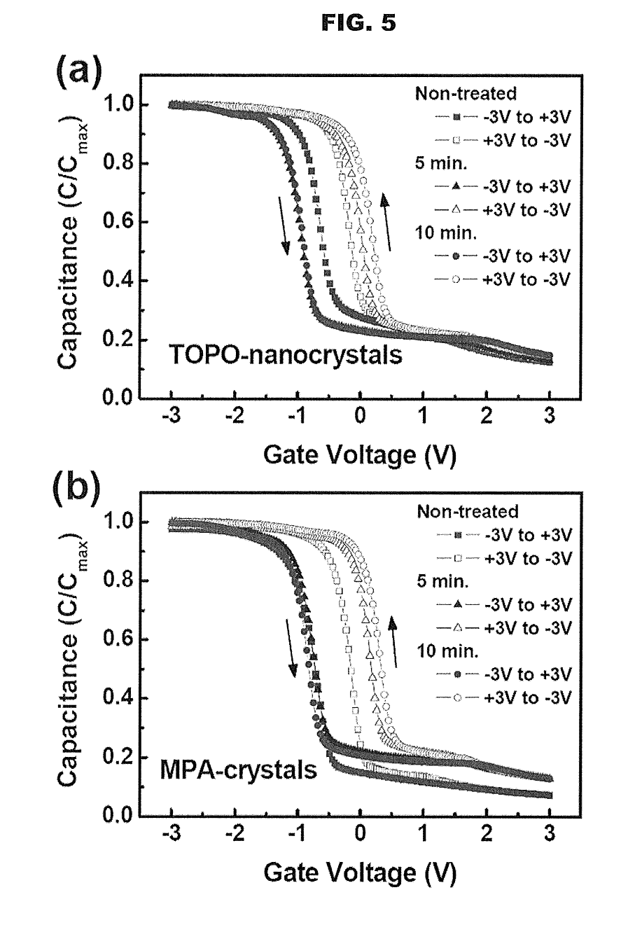

FIG. 5 shows the charging characteristics of devices including quantum dots with the ligand removed therefrom by plasma treatment.

FIG. 5(a) shows the C-V results of the TOPO-quantum dots at various plasma treatment times. As can be seen therein, as the plasma treatment time was increased, the C-V hysteresis width was increased. When the treatment time was 5 minutes, the flat band voltages in both sweep down and sweep up were shifted in the negative and positive directions, respectively, and, as a result, the hysteresis widths were increased. However, when the plasma treatment time was increased to 10 minutes, the flat band voltage in sweep down was not changed, and the flat band voltage in sweep up was shifted in the positive direction.

In the case of the MPA-quantum dots, as can be seen in FIG. 5(b), the C-V hysteresis width was increased with the increase in the plasma treatment time. However, in the case of the MPA-quantum dots, the flat band voltage in sweep down was not substantially changed, and the flat band voltage in sweep up was shifted in the positive direction with the increase in the plasma treatment time.

When the ligand on the surface of the quantum dots was removed by plasma treatment, the flat band voltage in sweep up by electron charging was shifted in the positive direction with the increase in the plasma treatment time. As a result, the charging memory effect of the quantum dots was increased.

According to the present invention, semiconductor quantum dots embedded in oxides have excellent electrical, chemical and mechanical stabilities. Also, with the embedded quantum dots, perfect compatibility with existing Si CMOS processes can be realized, and thus semiconductor quantum dots of various materials and sizes can be applied to memory devices in a relatively low cost. In addition, the light-emitting and light-receiving properties of semiconductor quantum dots are utilized, an electronic/photonic device combining the properties of a memory device that stores electrical signals with those of a memory device that can store and emit light signals can be easily realized on, for example, a Si substrate.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A non-volatile memory device comprising an oxide thin film formed on a substrate, wherein the oxide thin film comprises quantum dots embedded therein.

2. The non-volatile memory device according to claim 1, wherein the substrate is made of Si or GaAs semiconductor.

3. The non-volatile memory device according to claim 1, wherein the oxide is at least one selected from the group consisting of TiO₂, SiO₂, Hf₂O₃, Y₂O₃, ZrO₂, Al₂O₃, Cu₂O, BN, MnO and V₂O₃.

4. The non-volatile memory device according to claim 1, wherein the quantum dots are made of at least one selected from the group consisting of CdS, CdSe, CdSe/ZnS, PbS, CdTe, ZnS, ZnSe, ZnTe, GaN, GaP, GaAs, GaSb, AlN, AlP, AlAs, AlSb, InP, InAs, InSb and SiC.

5. The non-volatile memory device according to claim 1, wherein the quantum dot is in the state in which a ligand is removed.

6. A method for fabricating a non-volatile memory device comprising an oxide thin film formed on a substrate, the method comprising the steps of:
(A) coating a substrate with quantum dots; and
(B) depositing an oxide thin film on the substrate having the quantum dots coated thereon, whereby the oxide thin film is formed on the non-volatile memory device.

7. The method according to claim 6, wherein a ligand on the surface of the quantum dots used in step (A) is substituted with SHCH₂CH₂OOH (MPA).

8. The method according to claim 6, wherein the deposition in step (B) is performed by plasma metal organic chemical vapor deposition at 100-200° C.

9. The method according to claim 6, further comprising, between step (A) and step (B), a step of removing a ligand from the coated quantum dots.

10. The method according to claim 9, wherein the surface coated with the ligand is removed by subjecting the quantum dots to hydrogen plasma treatment at 50-150° C.

11. The method according to claim 7, wherein the deposition in step (B) is performed by plasma metal organic chemical vapor deposition at 100-200° C.

12. The method according to claim 7, further comprising, between step (A) and step (B), a step of removing a ligand from the coated quantum dots.

13. The method according to claim 12, wherein the surface coated with the ligand is removed by subjecting the quantum dots to hydrogen plasma treatment at 50-150° C.
